(19) United States
(12) Patent Application Publication
(10) Pub. No.: US 2026/0173916 A1
(43) Pub. Date: Jun. 18, 2026

(54) METHOD AND DEVICE FOR COMPACT STACKED MICROELECTRONICS PACKAGING WITH VERTICAL INTERCONNECTIVITY VIA WIRE BONDS

(71) Applicant: Rockwell Collins, Inc., Cedar Rapids, IA (US)

(72) Inventors: Reginald D. Bean, Center Point, IA (US); Bret W. Simon, West Liberty, IA (US)

(21) Appl. No.: 19/376,188

(22) Filed: Oct. 31, 2025

Related U.S. Application Data
(60) Provisional application No. 63/734,549, filed on Dec. 16, 2024.

(51) Int. Cl. H01L 23/538; H01L 23/31; H01L 23/49; H01L 23/498; H01L 23/60; H01L 25/065

(52) U.S. Cl. CPC H10W 70/614; H10W 72/50; H10W 74/117; H10W 90/00; H10W 90/701; H10W 42/60

(57) ABSTRACT

A stacked microelectronics package with vertical connectivity between interposer layers and integrated circuit (IC) dies or chips connected thereto includes a ring interposer attached around the edge or perimeter of a lower interposer layer and one or more bond wire arrays connected to the lower interposer layer and to the ring interposer, each bond wire arching above the ring interposer. After an overmold layer is added to the package atop the cavity enclosed by the ring interposer, the distal ends of each bond wire are exposed by vertical downward planing, grinding, or otherwise removing material from the ring interposer and overmold layer. The remaining ring interposer is also removed via lateral planing or grinding. Upper interposers or other components attached over the remaining distal ends of the bond wires electrically interconnect those components and the lower interposer layers via the bond wires.

### CROSS-REFERENCE TO RELATED APPLICATIONS

The present application is related to and claims the benefit of the earliest available effective filing dates from the following listed applications (the “Related Applications”) (e.g., claims earliest available priority dates for other than provisional patent applications (e.g., under 35 USC § 120 as a continuation in part) or claims benefits under 35 USC § 119(e) for provisional patent applications, for any and all parent, grandparent, great-grandparent, etc. applications of the Related Applications).

### Related Applications

U.S. Provisional Patent Application Ser. No. 63/734,549 filed Dec. 16, 2024 and having docket number 182480US01.

Said provisional patent application 63/734,549 is herein incorporated by reference in its entirety.

### BACKGROUND

As integrated circuit (IC) sizes continue to be aggressively reduced, logic densities increase to accommodate the growing need for higher processing performance. For example, ICs may be stacked vertically to minimize the total circuit board surface area consumed. The stacking of IC dies created a need for vertical interconnectivity within the various levels or layers of a stacked package. For example, a set of interposers may be stacked, each interposer containing one or more IC dies attached to either its upper or lower surface, with the interposer providing an interconnect between the dies on its upper surface and those on its lower surface. Further, the interposers provide interconnectivity between the package layers. For example, stacked higher-density interposers may likewise be stacked on a lower-density interposer which provides mechanical and electrical interfacing with the next level of assembly, e.g., a printed wiring board. However, the perimeter ball grid assemblies used to establish this vertical interconnectivity themselves consume a significant degree of circuit board surface area that might otherwise be occupied by additional IC dies and/or other components.

### SUMMARY

In a first aspect, a method for fabricating a stacked microelectronics package is disclosed. In embodiments, the method includes providing a lower interposer layer, one or more integrated circuit (IC) dies or chip assemblies electrically connected thereto. The method includes attaching a ring interposer over the lower interposer layer, e.g., over a perimeter or outer portion thereof, such that the ring interposer encloses an inner cavity over the lower interposer layer and connected IC die/s. The method includes electrically connecting the lower interposer layer and ring interposer via one or more bond wire arrays, each bond wire of the array arching above the upper face of the ring interposer between the ring interposer and the lower interposer layer. The method includes filling the inner cavity with an overmold layer. The method includes exposing a distal end of each bond wire, e.g., the proximal end connected to the lower interposer layer and secured beneath the overmold layer, by removing material in a downward (e.g., vertical, z-axis) direction from the package. For example, the downward removal may remove one or more layers of the ring interposer and overmold layer as well as the arched portion of each bond wire (as well as, e.g., the point where each bond wire connects to the ring interposer). The method includes removing the ring interposer from the package in at least one lateral direction (e.g., x-axis, y-axis) substantially orthogonal to the downward removal of material.

In some embodiments, the method further comprises adding an upper interposer layer above the remaining overmold layer such that the lower interposer layer and upper interposer layer are electrically connected via the exposed distal ends of the bond wires, which contact the upper interposer layer.

In some embodiments, the method further comprises adding a redistribution layer above the remaining overmold layer (e.g., atop the package). The method includes adding one or more further IC dies above the redistribution layer and electrically connected to the lower interposer layer via the exposed distal ends of the bond wires.

In some embodiments, the method includes adding conductive pads to the exposed distal ends of the bond wires.

In some embodiments, the method includes electrically connecting the ring interposer (and any internal infrastructure thereof) and lower interposer layer (and any internal infrastructure thereof) via ball grid array.

In some embodiments, the ring interposer and lower interposer layer incorporate vias, routing layers, and/or other internal infrastructure extending through the ring interposer and lower interposer layers (as well as ball grid arrays between the ring interposer and lower interposer layer) such that bond points on the upper face of the ring interposer are electrically connected to probe points on the lower face of the lower interposer layer.

In some embodiments, additional arrays of bond wires connect the ring interposer and lower interposer layer, substantially parallel to the first array of bond wires. For example, each array of bond wires connects its respective bond points on the ring interposer to the probe points through vias and routing layers extending through the ring interposer and lower interposer layer (as well as the ball grid array).

In some embodiments, the package includes additional rows of bond wires substantially parallel to the first row. For example, the bond points where each row of bond wires connect to the upper face of the ring interposer electrically connect to the probe points via a set of vias and/or routing layers extending through the ring interposer and the lower interposer layer (and connected via the ball grid array).

In some embodiments, the method includes placing additive components above the overmold layer (e.g., antenna components, surface-mount passive components, grounding lids, shielding lids, thermal conductors or spreaders), the additive components electrically connected to the lower interposer layer via the bond wire arrays.

In some embodiments, the method includes connecting the lower interposer layer to a center substrate (e.g., positioned within the inner cavity above the lower interposer layer, enclosed by the ring interposer) via additional arrays of bond wires. For example, the additional bond wires may arch over the center substrate between said center substrate and the lower interposer layer, the arched portions removed by the downward planing or grinding of material (including one or more layers of the center substrate) exposing the distal ends of the additional bond wires.

In some embodiments, the center substrate includes a thermally conductive material (e.g., diamond, glass); in other embodiments the center substrate includes a center interposer.

In a further aspect, a stacked microelectronics package with vertical interconnectivity is also disclosed. In embodiments, the package includes a lower interposer layer with one or more integrated circuit (IC) dies or chips electrically connected thereto, and an overmold layer substantially covering the lower interposer layer and IC dies. The package includes one or more bond wire arrays, each bond wire electrically connecting the lower interposer layer (e.g. via a proximal end beneath the overmold layer) and an exposed distal end. To attach the bond wire arrays, a ring interposer is first attached over the lower interposer layer, e.g., over a perimeter or outer portion of the lower interposer layer. The lower interposer layer and ring interposer layer are connected with bond wire arrays such that each bond wire arches over the ring interposer between the ring interposer and lower interposer layer. The overmold layer is added atop the bond wire arrays. The distal ends of each bond wire are exposed via downward (e.g., vertical, z-axis) removal of material from the package, such that portions of the ring interposer and overmold layer are removed along with the arched portions of each bond wire, thereby exposing the distal ends. Finally, the remaining ring interposer is removed via lateral (horizontal, x-axis and/or y-axis) removal of material from the package.

In some embodiments, the package further comprises one or more upper interposer layers stacked above the overmold layer and electrically connected to the lower interposer layer via the exposed bond wire arrays.

In some embodiments, the package further comprises a redistribution layer disposed above the overmold layer (above the package), and one or more additional IC dies disposed above the redistribution layer and electrically connected to the lower interposer layer via the redistribution layer and the bond wire arrays.

In some embodiments, conductive pads are added to the exposed distal ends of the bond wires.

In some embodiments, the ring interposer and lower interposer layer are electrically connected by one or more ball grid arrays.

In some embodiments, additional arrays of bond wires connect the ring interposer and lower interposer layer, substantially parallel to the first array of bond wires. For example, each array of bond wires connects its respective bond points on the ring interposer to the probe points through vias and routing layers extending through the ring interposer and lower interposer layer (as well as the ball grid array).

In some embodiments, the package includes additional rows of bond wires substantially parallel to the first row. For example, the bond points where each row of bond wires connect to the upper face of the ring interposer electrically connect to the probe points via a set of vias and/or routing layers extending through the ring interposer and the lower interposer layer (and connected via the ball grid array).

In some embodiments, the ring interposer and lower interposer layer further incorporate vias, routing layers, and other internal infrastructure extending though the ring interposer and lower interposer layer, and capable of providing electrical connectivity (along with, e.g., the ball grid arrays connecting the ring interposer and lower interposer layer) between bond points on the ring interposer (e.g., on an upper face thereof) and probe points below the lower interposer layer (e.g., on a lower face thereof).

In some embodiments, the package includes additive components disposed on the overmold layer or redistribution layer and electrically connected to the lower interposer layer via the bond wire arrays, e.g., antenna components, surface-mount passive components, grounding lids, shielding lids, and/or additional ball grid arrays.

In some embodiments, additional arrays of bond wires connect the ring interposer and lower interposer layer, substantially parallel to the first array of bond wires. For example, each array of bond wires connects its respective bond points on the ring interposer to the probe points through vias and routing layers extending through the ring interposer and lower interposer layer (as well as the ball grid array).

In some embodiments, the package includes additional rows of bond wires substantially parallel to the first row. For example, the bond points where each row of bond wires connect to the upper face of the ring interposer electrically connect to the probe points via a set of vias and/or routing layers extending through the ring interposer and the lower interposer layer (and connected via the ball grid array).

This Summary is provided solely as an introduction to subject matter that is fully described in the Detailed Description and Drawings. The Summary should not be considered to describe essential features nor be used to determine the scope of the Claims. Moreover, it is to be understood that both the foregoing Summary and the following Detailed Description are example and explanatory only and are not necessarily restrictive of the subject matter claimed.

### BRIEF DESCRIPTION OF THE DRAWINGS

The detailed description is described with reference to the accompanying figures. The use of the same reference numbers in different instances in the description and the figures may indicate similar or identical items. Various embodiments or examples (“examples”) of the present disclosure are disclosed in the following detailed description and the accompanying drawings. The drawings are not necessarily to scale. In general, operations of disclosed processes may be performed in an arbitrary order, unless otherwise provided in the claims. In the drawings:

FIG. 1 is a block diagram illustrating, in a profile view, a prior art stacked microelectronics package;

FIG. 2 is a block diagram illustrating, in a profile view, connectivity between two interposer layers according to the inventive concepts disclosed herein;

FIG. 3A is a block diagram illustrating, in a profile view, the fabrication of a stacked microelectronics package in a first stage according to the inventive concepts disclosed herein;

FIG. 3B is a block diagram illustrating, in a profile view, the fabrication of the stacked microelectronics package of FIG. 3A in a second stage;

FIG. 3C is a block diagram illustrating, in overhead and profile views, the fabrication of the stacked microelectronics package of FIG. 3A in a third stage;

FIG. 3D is a block diagram illustrating, in a profile view, the fabrication of the stacked microelectronics package of FIG. 3A in a fourth stage;

FIG. 3E is a block diagram illustrating, in a profile view, the fabrication of the stacked microelectronics package of FIG. 3A in a fifth stage;

FIG. 3F is a block diagram illustrating, in a profile view, the fabrication of the stacked microelectronics package of FIG. 3A in a sixth stage;

FIG. 3G is a block diagram illustrating, in a profile view, the stacked microelectronics package of FIGS. 3A through 3F incorporating off-vertical bond wire orientation;

FIG. 3H is a block diagram illustrating, in a profile view, the stacked microelectronics package of FIGS. 3A through 3F incorporating fan-out and looping bond wire orientations.

FIG. 4A is a block diagram illustrating, in a profile view, the stacked microelectronics package of FIGS. 3A through 3F incorporating an upper interposer layer;

FIG. 4B is a block diagram illustrating, in a profile view, the stacked microelectronics package of FIGS. 3A through 3F incorporating direct connection of additional integrated circuit (IC) dies or packages;

FIG. 5A is a block diagram illustrating, in a profile view, the stacked microelectronics package of FIG. 3C in a testing stage;

FIG. 5B is a block diagram illustrating, in a profile view, the stacked microelectronics package of FIG. 5A incorporating multiple arrays of bond wires;

FIGS. 6A through 6C are diagrammatic illustrations of the stacked microelectronics package of FIGS. 3A through 3F according to alternative configurations and/or alternative means of construction;

and FIGS. 7A through 7D are flow diagrams illustrating a method for fabricating a stacked microelectronics package according to example embodiments of this disclosure.

### DETAILED DESCRIPTION

Before explaining one or more embodiments of the disclosure in detail, it is to be understood that the embodiments are not limited in their application to the details of construction and the arrangement of the components or steps or methodologies set forth in the following description or illustrated in the drawings. In the following detailed description of embodiments, numerous specific details may be set forth in order to provide a more thorough understanding of the disclosure. However, it will be apparent to one of ordinary skill in the art having the benefit of the instant disclosure that the embodiments disclosed herein may be practiced without some of these specific details. In other instances, well-known features may not be described in detail to avoid unnecessarily complicating the instant disclosure.

As used herein a letter following a reference numeral is intended to reference an embodiment of the feature or element that may be similar, but not necessarily identical, to a previously described element or feature bearing the same reference numeral (e.g., 1, 1a, 1b). Such shorthand notations are used for purposes of convenience only and should not be construed to limit the disclosure in any way unless expressly stated to the contrary.

Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In addition, use of “a” or “an” may be employed to describe elements and components of embodiments disclosed herein. This is done merely for convenience and “a” and “an” are intended to include “one” or “at least one,” and the singular also includes the plural unless it is obvious that it is meant otherwise.

Finally, as used herein any reference to “one embodiment” or “some embodiments” means that a particular element, feature, structure, or characteristic described in connection with the embodiment is included in at least one embodiment disclosed herein. The appearances of the phrase “in some embodiments” in various places in the specification are not necessarily all referring to the same embodiment, and embodiments may include one or more of the features expressly described or inherently present herein, or any combination or sub-combination of two or more such features, along with any other features which may not necessarily be expressly described or inherently present in the instant disclosure.

Broadly speaking, embodiments of the inventive concepts disclosed herein are directed to a device and method of fabrication for vertically interconnected stacked integrated circuit (IC) packaging. For example, stacked IC packages as disclosed herein may incorporate novel approaches to additive manufacturing that provide for vertical interconnection on a significantly smaller footprint through the application and truncation of wire bonding, removing the outer ball grid array and freeing up any surface area otherwise consumed thereby. Throughout the fabrication process, material may be removed from the package in both vertical and lateral directions.

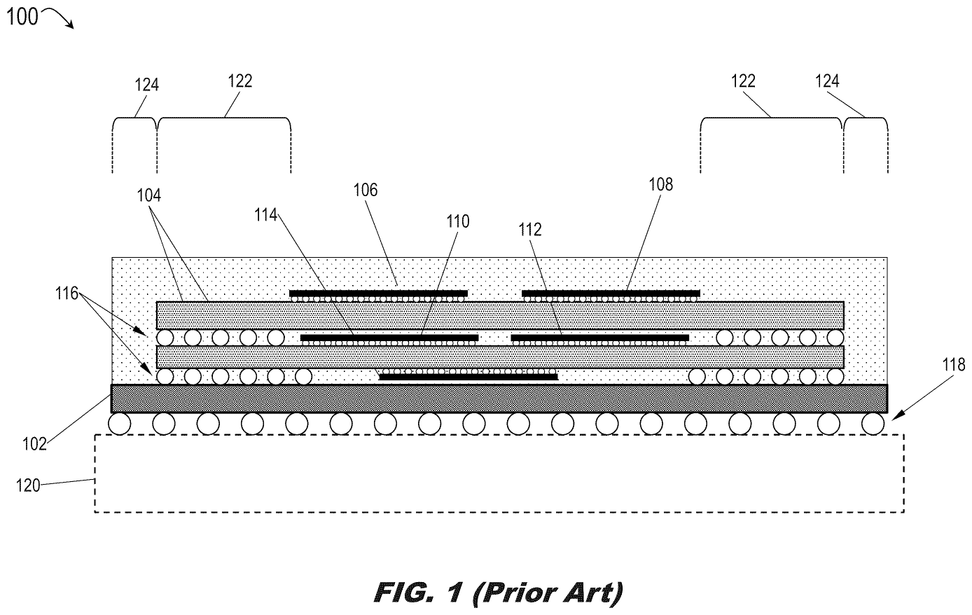

Referring to FIG. 1, a prior art IC package 100 is shown. The prior art IC package 100 may include lower-density interposers 102; higher-density interposers 104; IC dies 106, 108, 110, 112, 114; inner ball grid arrays 116; and outer ball grid array 118.

With respect to the prior art IC package 100, it may be noted that vertical interconnectivity between the higher-density interposers 104 is provide via the inner ball grid arrays 116, and vertical interconnectivity between the lower-density interposer 102 and the next assembly level 120 under the lower-density interposer (e.g., printed wiring board). It may further be noted that the inner ball grid arrays 116 and outer ball grid array 118 respectively consume a considerable portion 122, 124 of surface area available to the underlying printed wiring board or circuit board.

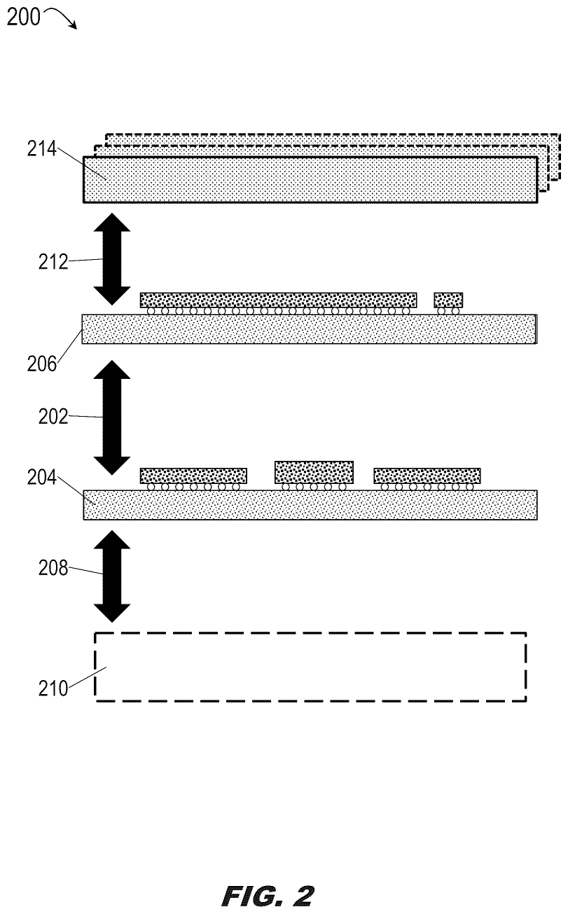

Referring now to FIG. 2, a compact stacked microelectronics package 200 is shown. In embodiments, the compact stacked microelectronics package 200 may provide vertical interconnectivity (202) between, e.g., a lower interposer layer 204 and an upper interposer layer 206 without the need for ball grid arrays (116, 118; see FIG. 1) or the board surface area (122, 124; see FIG. 1) consumed thereby. Further, the lower interposer layer 204 may be provided with vertical interconnectivity 208 to the next assembly level 210 while eliminating the outer ball grid array 118. Similarly, the upper interposer layer 206 may be provided with vertical interconnectivity 212 to one or more additional interposer layers 214 stacked over the upper interposer layer. In some embodiments, the lower interposer layer 204 may generally be a higher-density interposer and the upper interposer layer 206 (and any additional interposer layers 214 stacked thereupon) may be a higher-density or lower-density interposer.

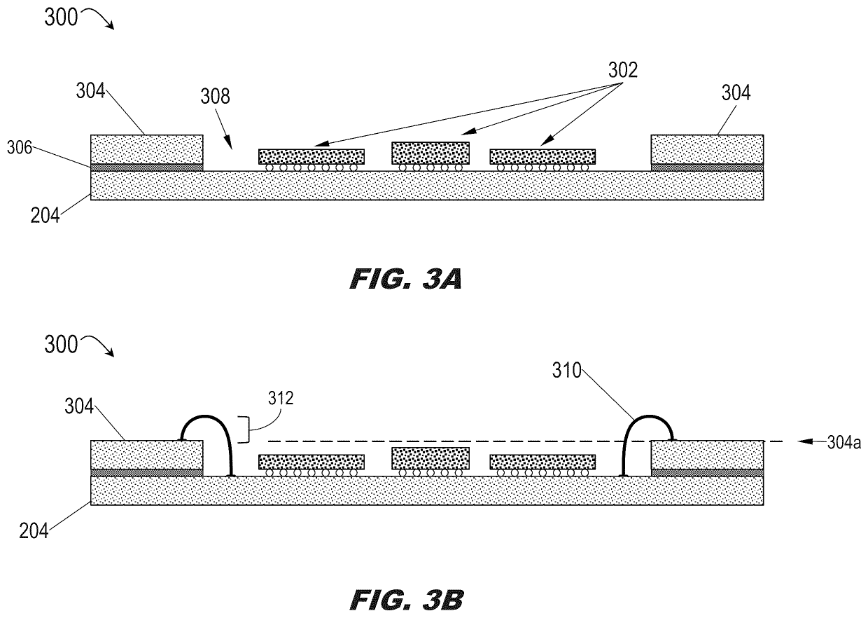

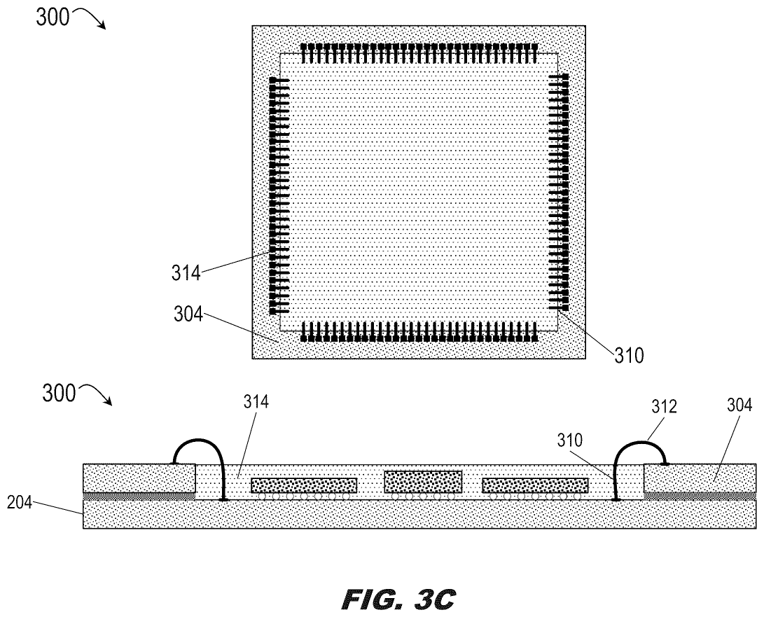

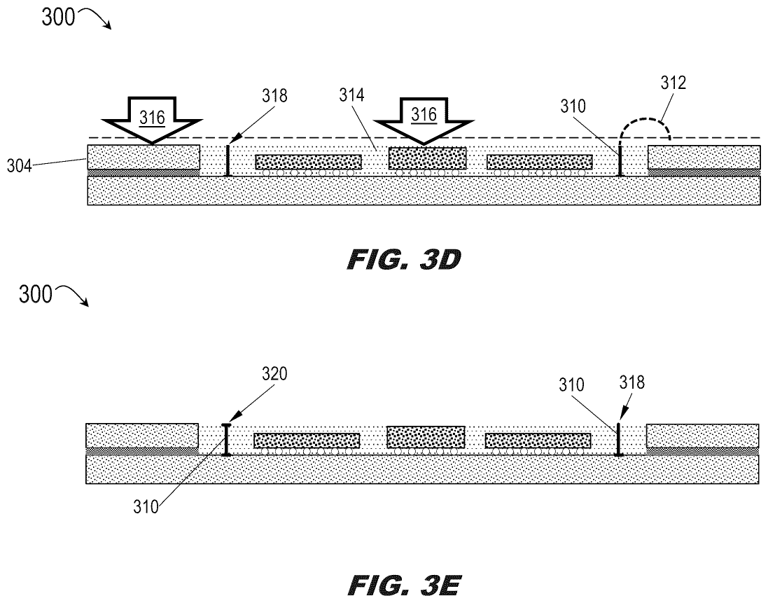

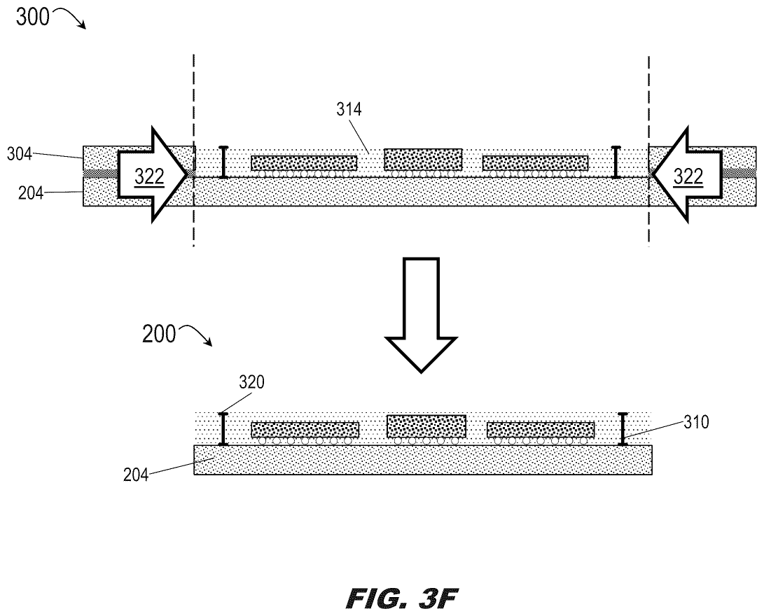

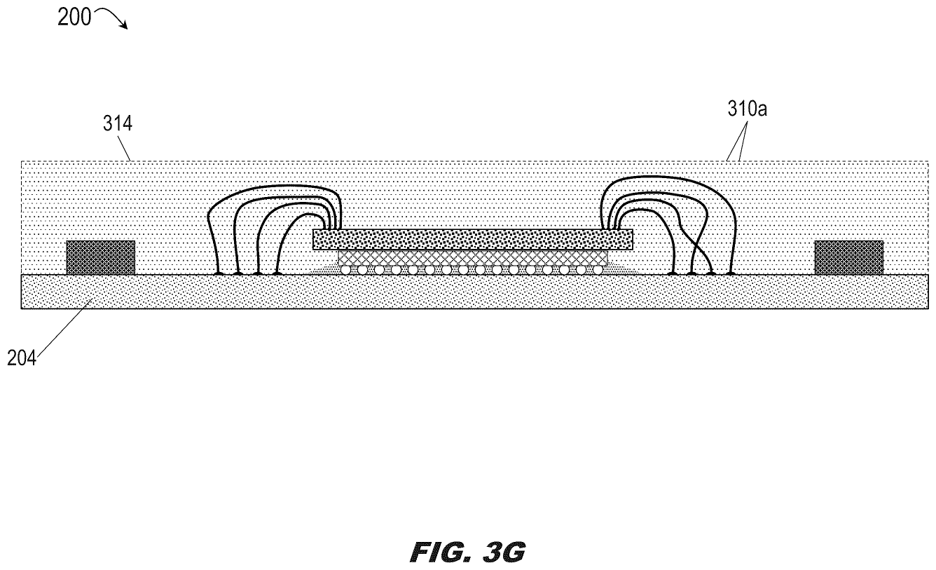

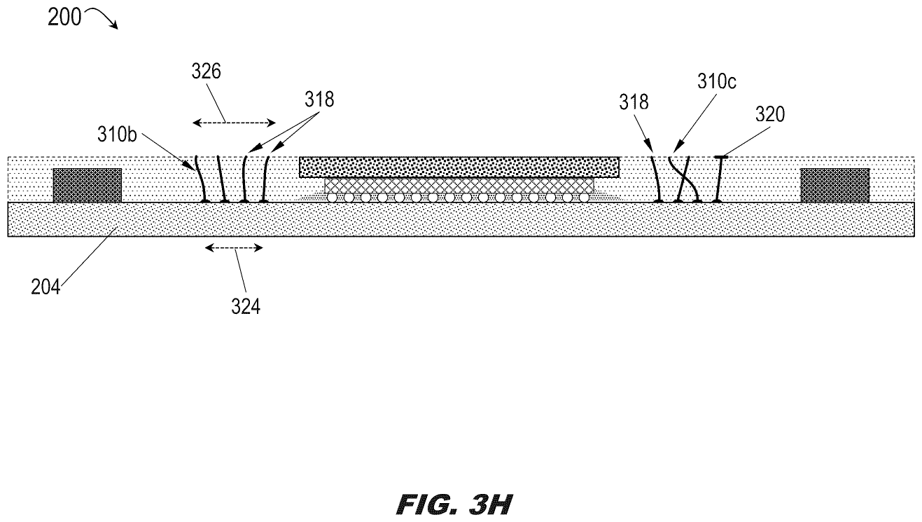

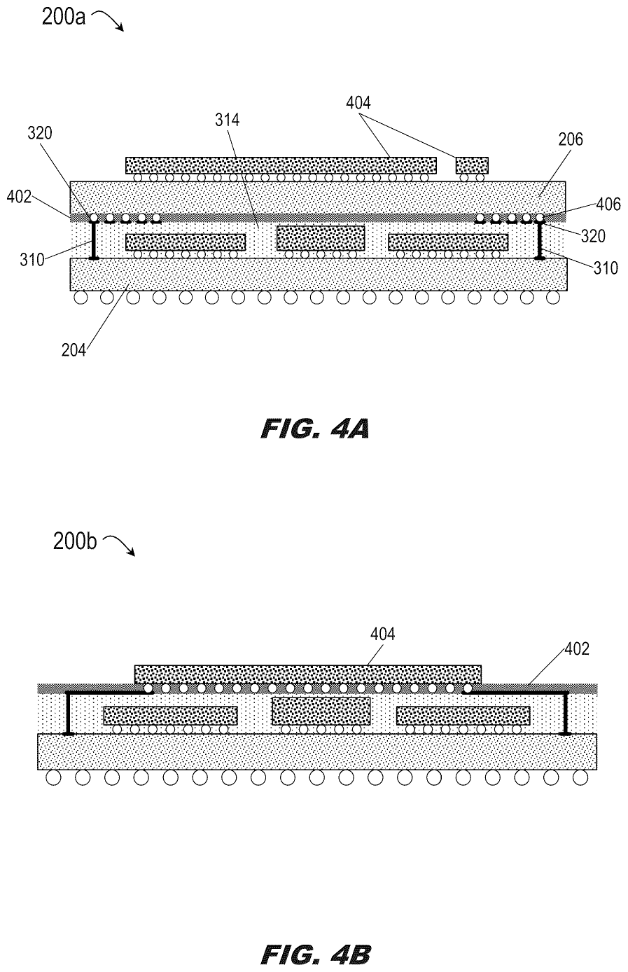

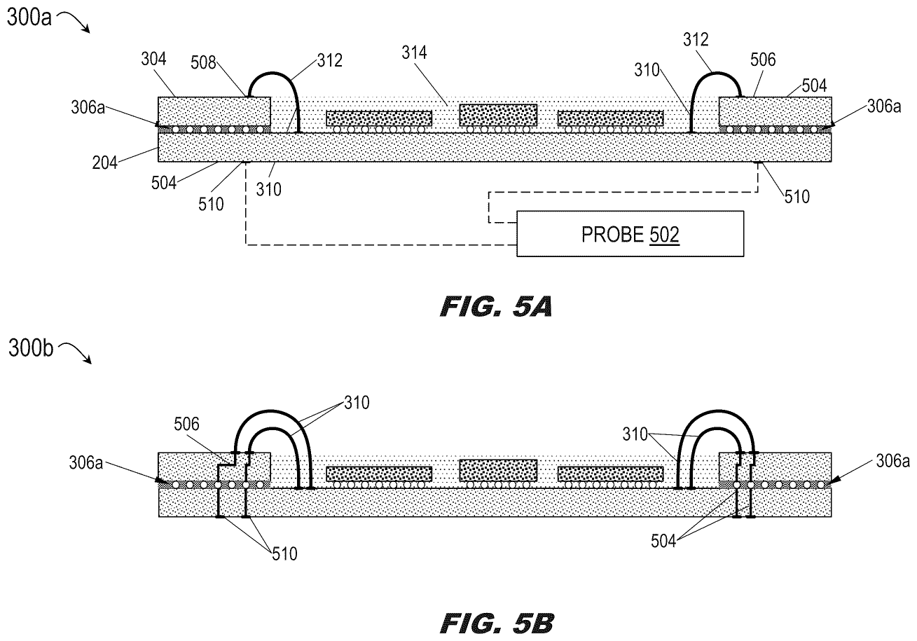

Referring generally to FIGS. 3A through 3F, the compact stacked microelectronics package 200 also shown by FIG. 2 may be fabricated via a multi-step process of additive manufacturing and multidirectional material removal.

Referring in particular to FIG. 3A, the compact stacked microelectronics package 200 may begin as a microelectronics assembly 300 consisting of one or more integrated circuit (IC) dies 302 attached to a lower interposer layer 204. In embodiments, a ring interposer 304 may be attached (e.g., via adhesive 306) around a perimeter of the lower interposer layer 204, leaving an exposed cavity 308 within the width of the ring interposer wherein the IC dies 302 are attached.

Referring also to FIG. 3B, the microelectronics assembly 300 is shown in a second stage of the fabrication process. In embodiments, one or more arrays of bond wires 310 may be placed from the lower interposer layer 204 to the ring interposer 304, providing connectivity between the two interposer layers. For example, each bond wire 310 may include an arched portion 312 between the lower interposer layer 204 and ring interposer 304, the arched portion protruding or extending above the highest plane 304a of the ring interposer.

Referring also to FIG. 3C, the microelectronics assembly 300 is shown in a third stage of the fabrication process. In embodiments, the exposed cavity (308; see FIG. 3A) is filled with overmolding material, creating an overmold layer 314 coplanar with the ring interposer 304. For example, the overmolding material may partially encapsulate the arrays of bond wires 310, such that the arched portion 312 may partially extend above the overmold layer 314 and a proximate portion of each bond wire, e.g., in contact with the lower interposer layer 204, may extend above the lower interposer layer at a substantially vertical angle relative to the lower interposer layer, held at said angle by the overmolding material.

Referring also to FIG. 3D, the microelectronics assembly 300 is shown in a fourth stage of the fabrication process. In embodiments, the microelectronics assembly 300 may be ground or planed in a downward direction 316 (e.g., vertical direction, z-axis direction) to remove material therefrom. For example, one or more layers may be removed from the highest point of the ring interposer 304 and/or the overmold layer 314. Further, the arched portion 312 of each bond wire 310 may be removed, such that a proximate portion of each bond wire remains embedded within the overmold layer 314 and a distal end 318 of each bond wire is exposed.

Referring also to FIG. 3E, the microelectronics assembly 300 is shown in a fifth stage of the fabrication process. In embodiments, conductive pads 320 may be attached to the exposed distal end 318 of each bond wire 310.

Referring also to FIG. 3F, the microelectronics assembly 300 is shown in a sixth stage of the fabrication process. In embodiments, portions of the ring interposer 304, overmold layer 314, and/or lower interposer layer 204 may be removed in one or more lateral directions 322 (e.g., x-axis and y-axis directions; orthogonal to the downward/vertical/z-axis direction 316 shown by FIG. 3D).

By removing material in lateral as well as vertical directions, the resulting compact stacked microelectronics package 200 may consume less surface area than a conventional ring-interposer package while providing vertical connectivity (202; see FIG. 2) with the lower interposer layer 204 via the conductive pads 320 and embedded bond wires 310.

Referring now to FIGS. 3G and 3H, in some embodiments the compact stacked microelectronics package 200 fabricated according to the disclosure shown by FIGS. 3A through 3F above may incorporate controlled non-vertical orientations of the arrayed bond wires 310a-310c. For example, referring in particular to FIG. 3G, the bond wires 310a may be oriented diagonally (e.g., at an angle not substantially vertical, as shown by FIGS. 3A through 3F above) and held at a substantially controlled angle by the overmold layer 314 in order to target a substantially controlled XY location within the pattern of distal ends 318 (see FIGS. 3D and 3E).

Referring in particular to FIG. 3H, the arrays of bond wires 310b-310c may be oriented such that the upper layer (e.g., the distal ends 318 of the bond wires 310b) and lower layer (e.g., the lower interposer layer 204) have different array footprints. For example, the bond wires 310b may be oriented to fan out at controlled off-vertical angles from a narrower pitch 324 with respect to the lower interposer layer 204 to a wider pitch 326 with respect to the distal ends 318. Similarly, in some embodiments bond wires 310c may be looped through the inner cavity 308 non-vertically with respect to multiple dimensions. For example, looped bond wires 310c may allow for swapping of input/output (I/O) or other pins as well as non-one-to-one (1:1) arrangements via which, e.g., multiple ground pins may be collectively bussed to an upper conductive pad 320 or distal end 318.

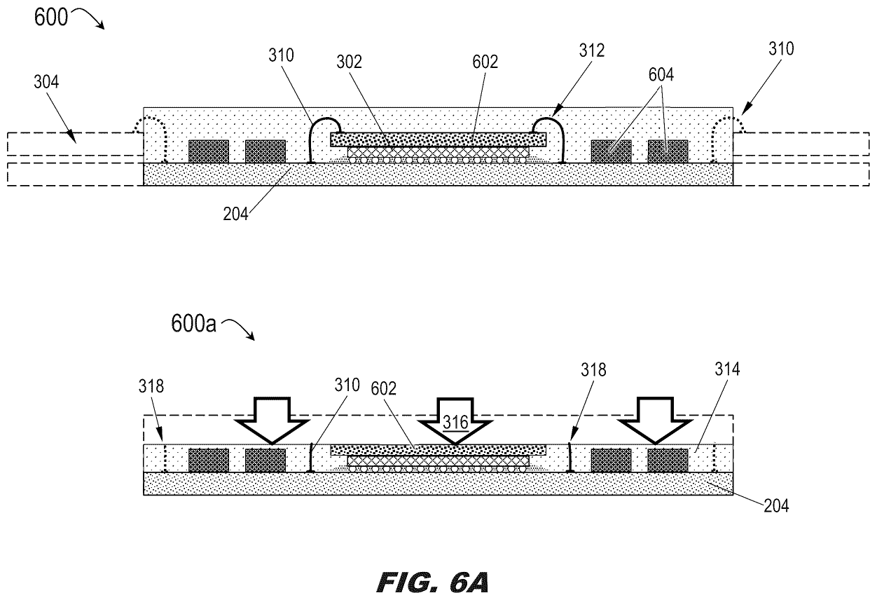

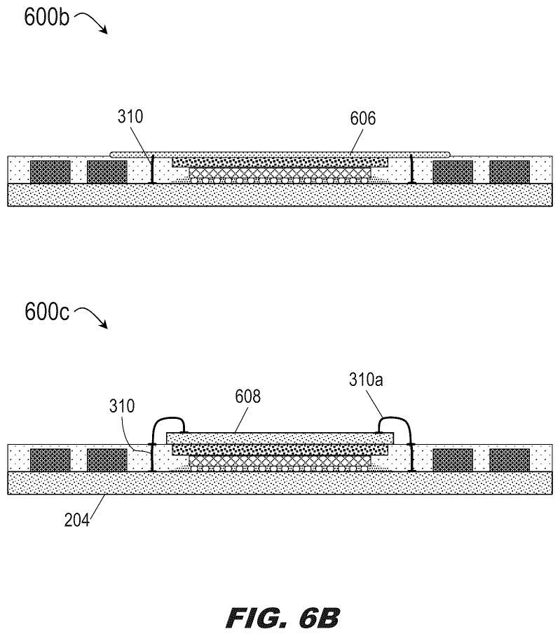

Referring now to FIG. 4A, the compact stacked microelectronics package 200a may be implemented and may function identically to the compact stacked microelectronics package 200 shown by FIG. 3F, except for the addition of a redistribution layer 402 and next-layer attachment over the top of the package 200, e.g., the remaining overmold layer 314 and conductive pads 320 connected to the embedded bond wires 310. For example, an upper interposer layer 206 and IC dies 404 connected thereto may be stacked on top of the redistribution layer 402. In embodiments, vertical connectivity between the lower and upper interposer layers 204, 206 may be provided by the ball grid array 406 of the upper interposer layer and the conductive pads 320 and embedded bond wires 310. As previously noted, in embodiments additional interposer layers (214; see FIG. 2), and IC dies 404 attached thereto, may be stacked upon the upper interposer layer 206. For example, the additional interposer layers 214 and IC dies 404 attached thereto may likewise be configured for vertical connectivity (212; see FIG. 2) with the upper interposer layer 206, and by extension the lower interposer layer 204 via embedded bond wires 310 using the process disclosed by FIGS. 3A through 3F generally.

Referring now to FIG. 4B, the compact stacked microelectronics package 200b is shown. In some embodiments, one or more packaged IC dies 404 may be placed directly on the redistribution layer 402.

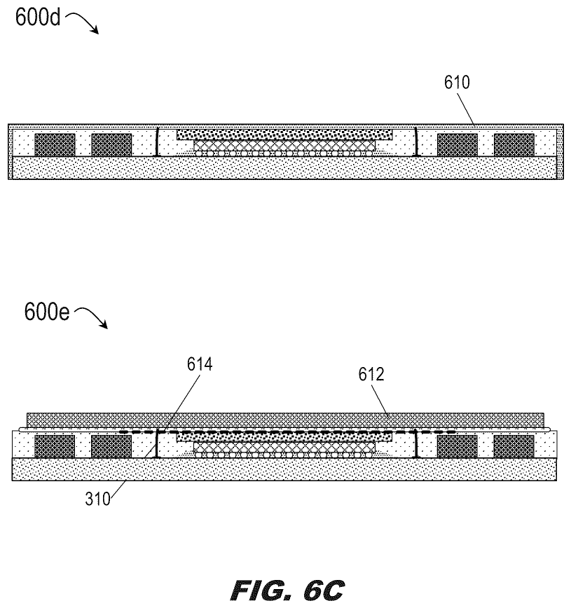

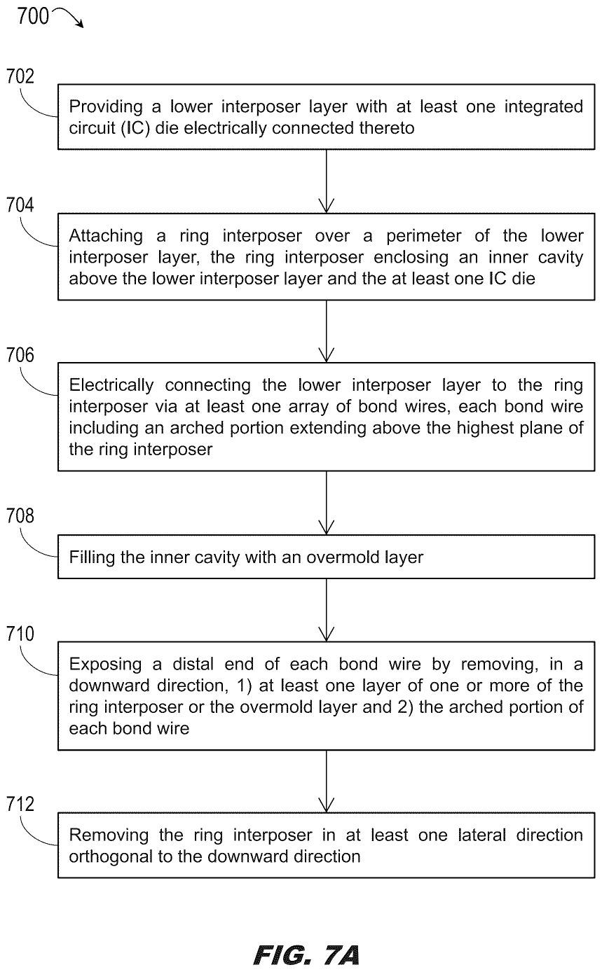

Referring now to FIG. 5A, the microelectronics assembly 300a may be implemented and may function similarly to the microelectronics assembly 300 shown by FIG. 3C, except that the microelectronics assembly 300a may be configured for through package connectivity in order to allow electrical testing (e.g., via a probe station 502 underlying the lower interposer layer 204) of the IC dies 302 and/or bond wires 310 prior to the downward/vertical removal (316; see FIG. 3D) of the arched portions 312, ring interposer 304, and/or overmold layer 314. In some embodiments, a ring interposer 304 may be attached (via, e.g., ball grid array 306a) around a perimeter of the lower interposer layer 204, leaving an exposed cavity 308 (see FIG. 3A) within the width of the ring interposer wherein the IC dies 302 are attached. For example, the internal design of the ring interposer 304 and the lower interposer layer 204 may include vias 504, routing layers 506, and/or other connective infrastructure such that the top bond point 508 of the bond wire 310 (located on the ring interposer 304) is electrically connected to a probe point 510 on the bottom surface of the lower interposer layer. Further, vias 504 and/or bond wires within the ring interposer 304 may be electrically connected to vias or bond wires within the lower interposer layer 204 via the ball grid array 306a.

Referring also to FIG. 5B, the microelectronics assembly 300b may be implemented and may function similarly to the microelectronics assembly 300a shown by FIG. 5A, except that the microelectronics assembly 300a may include two or more overlapping arrays of bond wires 310 and corresponding vias 504 (and/or other connective infrastructure, e.g., routing layers 506) electrically connected through the ring interposer 304, ball grid array 306a, and lower interposer layer 204 to the probe point 510 for testing with the probe station 502.

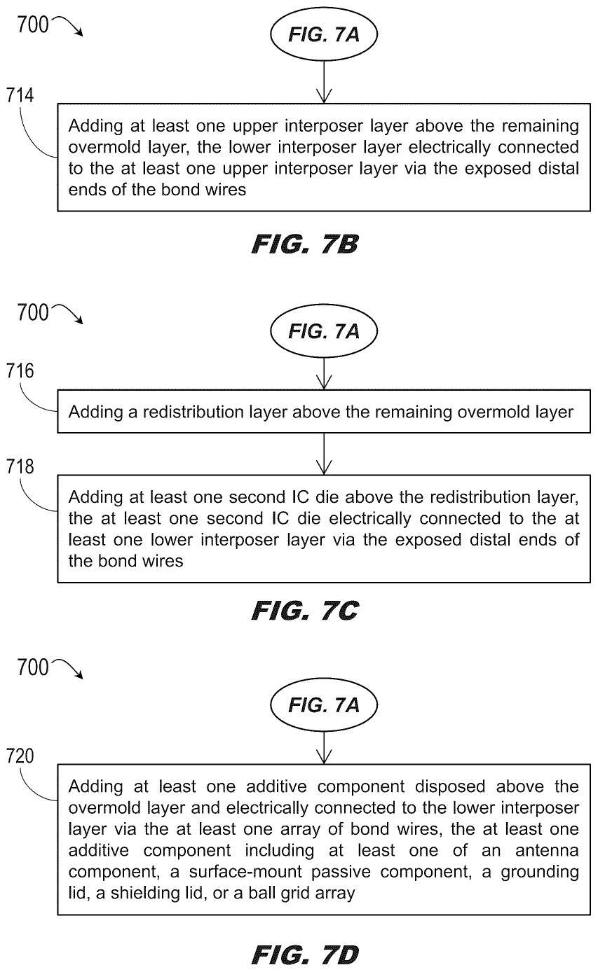

Referring now to FIG. 6A, the microelectronics assembly 600 may be implemented and may function similarly to the microelectronics assembly 300 of FIGS. 3A through 3F, except that the microelectronics assembly 600 may be fabricated without a ring interposer 304, but instead with a center bond wire attachment substrate 602 using a similar bond wire interconnect scheme for connectivity to the lower interposer layer 204. In some embodiments, fabrication of the microelectronics assembly 600 may incorporate the ring interposer 304 as well as the center substrate 602, whereby one or more arrays of bond wires 310 connect both the ring interposer and the center substrate to the lower interposer layer 204 prior to the removal of material.

In embodiments, the microelectronics assembly 600 may include one or more arrays of bond wires 310 connected to the lower interposer layer 204 and to the center substrate 602 of the microelectronics assembly, such that the center substrate is taller or farther above the lower interposer layer than any other component 604 or IC die 302 of the assembly. For example, the arched portion 312 of each bond wire 310 may extend above the center substrate 602.

In embodiments, the microelectronics assembly 600a may reflect the removal (grinding, planing) of material in a downward direction 316. For example, portions of the center substrate 602, the overmold layer 314, and/or arched portions 312 of the bond wires 310 may be removed, exposing the distal ends 318 of the bond wires.

In embodiments, referring also to FIG. 6B, the microelectronics assemblies 600b, 600c may reflect the mounting of additive components over the microelectronics assembly 600a, such that vertical connectivity between additive components mounted atop the microelectronics assemblies (e.g., over a redistribution layer (402; see FIG. 4A)) may be provided via the bond wires 310. For example, referring in particular to the microelectronics assembly 600b, antenna-in-package components or other patterned components 606 may be mounted over the microelectronics assembly. Similarly, referring in particular to the microelectronics assembly 600c, non-patterned components 608 (e.g., conformal shields, components applied via deposition) may be disposed over the microelectronics assembly.

In embodiments, referring also to FIG. 6C, the microelectronics assembly 600d may include a non-patterned conformal shield 610 applied via deposition) mounted atop the assembly. Similarly, in embodiments the microelectronics assembly 600e may include a grounding or shielding lid 612 applied, e.g., via electrically conductive adhesive 614. For example, the grounding or shielding lid 612 may be grounded via the bond wires 310 connected thereto. In embodiments where the shielding lid 612 is in contact (e.g., thermal contact or communication) with an exposed center substrate 602 (e.g., exposed via the downward or vertical removal of material as shown by the microelectronics assembly 600a of FIG. 6A), the center substrate may be formed from a thermally conductive material such as diamond or glass. In some embodiments, the center substrate 602 may serve as an interposer layer.

Referring now to FIG. 7A, the method 700 may be implemented for fabrication of the compact stacked microelectronics package 200 and may include the following steps.

At a step 702, a lower interposer layer is provided with one or more integrated circuit (IC) dies or packages attached thereto (e.g., to an upper or lower surface).

At a step 704, a ring interposer is attached over a perimeter of the lower interposer layer, e.g., around the edge of the lower interposer layer to a width of the ring interposer, such that the ring interposer encloses an internal cavity above the lower interposer layer and the one or more IC dies or packages are disposed within said internal cavity. In some embodiments, the ring interposer and lower interposer layer are electrically connected via ball grid array.

At a step 706, the ring interposer and lower interposer layer are connected via one or more arrays of bond wires, e.g., linear arrays of two or more bond wires, each bond wire connecting the lower interposer layer to the ring interposer with an arched portion in between extending above the ring interposer. In some embodiments, the arrangement of bond wires may be a polygonal arrangement of bond wire arrays, e.g., a square or rectangle in alignment with the shape of the internal cavity. In some embodiments, the arrangement of bond wires includes two or more overlapping rows of bond wires. In some embodiments, the ring interposer and lower interposer layer may include additional bond wires, vias, routing layers, and/or additional internal infrastructure capable (along with the ball grid array connecting the ring interposer and lower interposer layer) of electrically connecting a bond point on the upper face of the ring interposer to a probe point on the lower face of the lower interposer layer, such that the bond point is electrically testable by a probe station connected to the probe point prior to any removal of material.

At a step 708, the internal cavity is filled with an overmold material to create an overmold layer, e.g., coplanar with the ring interposer.

At a step 710, the distal ends of the bond wires are exposed by removal of material (e.g., grinding, planing) in a downward direction (e.g., relative to the z-axis of the stacked microelectronics package), removing the arched portions of the bond wires as well as one or more layers of the ring interposer and/or overmold layer. In some embodiments, conductive pads are added to the exposed distal ends of the bond wires.

At a step 712, the ring interposer (e.g., and that part of the lower interposer layer directly under the ring interposer to which the ring interposer is attached) is removed via the removal of material in at least one lateral direction (e.g., relative to the x-axis and/or y-axis of the package) orthogonal to the downward direction.

Referring also to FIG. 7B, the method 700 may include an additional step 714. At the step 714, an upper interposer layer is added above the remaining overmold layer of the compact stacked microelectronics package, the upper interposer layer electrically connected to the lower interposer layer via the arrays of bond wires and exposed distal ends of the bond wires. In some embodiments, additional upper interposer layers similarly configured with embedded bond wires for vertical connectivity are stacked above the upper interposer layer.

Referring also to FIG. 7C, the method 700 may include additional steps 716 and 718. At the step 716, a redistribution layer is added above the remaining (e.g., unremoved) overmold layer.

At the step 718, one or more additional IC dies or packages are attached over the redistribution layer, with vertical connectivity provided to the additional IC dies via the embedded bond wires.

Referring also to FIG. 7D, the method 700 may include an additional step 720. At the step 720, one or more additive components are added over the remaining overmold layer, e.g., antenna components, surface-mount passive components, grounding lids, shielding lids.

### CONCLUSION

It is to be understood that embodiments of the methods disclosed herein may include one or more of the steps described herein. Further, such steps may be carried out in any desired order and two or more of the steps may be carried out simultaneously with one another. Two or more of the steps disclosed herein may be combined in a single step, and in some embodiments, one or more of the steps may be carried out as two or more sub-steps. Further, other steps or sub-steps may be carried in addition to, or as substitutes to one or more of the steps disclosed herein.

Although inventive concepts have been described with reference to the embodiments illustrated in the attached drawing figures, equivalents may be employed and substitutions made herein without departing from the scope of the claims. Components illustrated and described herein are merely examples of a system/device and components that may be used to implement embodiments of the inventive concepts and may be replaced with other devices and components without departing from the scope of the claims. Furthermore, any dimensions, degrees, and/or numerical ranges provided herein are to be understood as non-limiting examples unless otherwise specified in the claims.

We claim:

1. A method of fabricating a stacked microelectronics package, the method comprising:
providing a lower interposer layer with at least one integrated circuit (IC) die electrically connected thereto;
attaching a ring interposer over a perimeter of the lower interposer layer, the ring interposer enclosing an inner cavity above the lower interposer layer and the at least one IC die;
electrically connecting the lower interposer layer to the ring interposer via at least one array of bond wires, each bond wire including an arched portion extending above a highest plane of the ring interposer;
filling the inner cavity with an overmold layer;
exposing a distal end of each bond wire by removing, in a downward direction, 1) at least one layer of one or more of the ring interposer or the overmold layer and 2) the arched portion of each bond wire; and
removing the ring interposer in at least one lateral direction orthogonal to the downward direction.

2. The method of claim 1, further comprising:
adding at least one upper interposer layer above the remaining overmold layer, the at least one upper interposer layer electrically connected to the lower interposer layer via the exposed distal ends of the bond wires.

3. The method of claim 1, wherein the at least one IC die is a first IC die, further comprising:
adding a redistribution layer above the remaining overmold layer; and
adding at least one second IC die above the redistribution layer, the at least one second IC die electrically connected to the at least one lower interposer layer via the exposed distal ends of the bond wires.

4. The method of claim 1, wherein exposing a distal end of each bond wire includes:
attaching a conductive pad to each exposed distal end.

5. The method of claim 1, wherein electrically connecting the lower interposer layer to the ring interposer via at least one array of bond wires includes:
electrically connecting the lower interposer layer to the ring interposer via at least one ball grid array.

6. The method of claim 5, wherein attaching a ring interposer over a perimeter of the lower interposer layer includes:
electrically connecting the ring interposer and the array of bond wires to at least one probe station disposed below the lower interposer layer via at least one of a first via or a first routing layer extending through the ring interposer and at least one of a second via or a second routing layer extending through the lower interposer layer, the at least one of a first via or a first routing layer and the at least one of a second via or a second routing layer electrically connected via the at least one ball grid array.

7. The method of claim 6, wherein the at least one array of bond wires is a first array, and wherein attaching a ring interposer over a perimeter of the lower interposer layer includes:
electrically connecting at least one second array of bond wires to the at least one probe station, the at least one second array parallel to the first array; via at least one of a third via or a third routing layer extending through the ring interposer and at least one of a fourth via or a fourth routing layer extending through the lower interposer layer, the at least one of a third via or a third routing layer and the at least one of a third via or a third routing layer electrically connected via the ball grid array.

8. The method of claim 1, further comprising:
adding at least one additive component disposed above the overmold layer and electrically connected to the lower interposer layer via the at least one array of bond wires, the at least one additive component including at least one of an antenna component, a surface-mount passive component, a grounding lid, a shielding lid, or a ball grid array.

9. The method of claim 1, wherein the at least one array of bond wires is a first array, and wherein:
electrically connecting the lower interposer layer to the ring interposer via at least one array of bond wires includes:
electrically connecting the lower interposer layer to a center substrate via at least one second array of bond wires, the center substrate disposed over at least one component within the inner cavity; and
wherein exposing a distal end of each bond wire by removing, in a downward direction, 1) at least one layer of one or more of the ring interposer or the overmold layer and 2) the arched portion of each bond wire includes:
removing, in a downward direction, at least one layer of the center substrate.

10. The method of claim 9, wherein the center substrate includes at least one of a thermally conductive material or an interposer layer.

11. A stacked microelectronics package comprising:
a lower interposer layer including at least one integrated circuit (IC) die electrically connected thereto;
an overmold layer covering the lower interposer layer and the at least one IC die;
at least one array of bond wires, each bond wire having a proximal end electrically connected to the lower interposer layer and an exposed distal end, the at least one array of bond wires placed by:
attaching a ring interposer over a perimeter of the lower interposer layer,
connecting the lower interposer layer and the ring interposer via the at least one array of bond wires, each bond wire including an arched portion extending above the ring interposer,
adding the overmold layer to a cavity enclosed by the ring interposer,
exposing the distal ends of each bond wire by removing, in a downward direction, 1) at least one layer corresponding to one or more of the ring interposer or the overmold layer and 2) the arched portion of each bond wire, and
removing the ring interposer in at least one lateral direction orthogonal to the downward direction.

12. The stacked microelectronics package of claim 11, further comprising:
an upper interposer layer disposed above the overmold layer, the upper interposer layer electrically connected to the lower interposer layer via the at least one array of bond wires.

13. The stacked microelectronics package of claim 11, wherein the at least one IC die is a first IC die, further comprising:
a redistribution layer disposed above the remaining overmold layer; and
at least one second IC die disposed above the redistribution layer, the at least one second IC die electrically connected to the at least one lower interposer layer via the exposed distal ends of the bond wires.

14. The stacked microelectronics package of claim 11, wherein the at least one array of bond wires includes at least one bond wire to which a conductive pad is attached at the distal end.

15. The stacked microelectronics package of claim 11, wherein the ring interposer and the lower interposer layer are electrically connected via at least one ball grid array.

16. The stacked microelectronics package of claim 15, further comprising:
at least one of a first via or a first routing layer extending through the ring interposer; and
at least one of a second via or a second routing layer extending through the lower interposer layer;
wherein the at least one of a first via or a first routing layer and the at least one of a second via or a second routing layer are electrically connected via the at least one ball grid array; and
wherein the ring interposer and the at least one array of bond wires are electrically connectible to at least one probe station disposed below the lower interposer layer via the at least one of a first via or a first routing layer and the at least one of a second via or a second routing layer.

17. The stacked microelectronics package of claim 16, wherein the at least one array of bond wires is a first array, and:
wherein the at least one array of bond wires includes at least one second array of bond wires, the at least one second array parallel to the first array; and
wherein the at least one second array of bond wires is electrically connectible to the at least one probe station via at least one of a third via or a third routing layer extending through the ring interposer and at least one of a fourth via or a fourth routing layer extending through the lower interposer layer, the at least one of a third via or a third routing layer and the at least one of a third via or a third routing layer electrically connected via the ball grid array.

18. The stacked microelectronics package of claim 11, further comprising:
adding at least one additive component disposed above the overmold layer and electrically connected to the lower interposer layer via the at least one array of bond wires, the at least one additive component including at least one of an antenna component, a surface-mount passive component, a grounding lid, a shielding lid, or a ball grid array.

19. The stacked microelectronics package of claim 11, wherein the at least one array of bond wires is a first array, further comprising:
at least one center substrate disposed over at least one component within the cavity;
wherein the at least one array of bond wires includes at least one second array of bond wires having a proximal end electrically connected to the lower interposer layer and an exposed distal end, and
wherein the at least one second array of bond wires is placed by:
connecting the lower interposer layer and the at least one center substrate via the at least one second array of bond wires, each bond wire of the second array including an arched portion extending above the center substrate, and
exposing the distal ends of each bond wire of the at least one second array by removing, in a downward direction, 1) at least one layer corresponding to one or more of the center substrate or the overmold layer and 2) the arched portion of each bond wire of the at least one second array.

20. The stacked microelectronics package of claim 19, wherein the center substrate includes at least one of a thermally conductive material or an interposer layer.
